(19) United States
(12) Patent Application Publication
(10) Pub. No.: US 2015/0072119 A1
(43) Pub. Date: Mar. 12, 2015

(54) MULTI-LAYER STRUCTURE INCLUDING AN INTERLAYER TO REDUCE STRESS IN THE STRUCTURE AND METHOD OF FORMING SAME

(71) Applicants: The Regents of the University of Colorado, a body corporate, Denver, CO (US); E.I. du Pont de Nemours and Company, Wilmington, DE (US)

(72) Inventors: Steven George, Boulder, CO (US); Shih-Hui Jen, Boulder, CO (US); Peter Carcia, Wilmington, DE (US); Robert McLean, Wilmington, DE (US)

(21) Appl. No.: 14/394,253

(22) PCT Filed: Apr. 12, 2013
(86) PCT No.: PCT/US13/36450

§ 371 Date: Oct. 13, 2014

Related U.S. Application Data
(60) Provisional application No. 61/623,455, filed on Apr. 12, 2012.

(51) Int. Cl. C23C 16/455; C23C 16/34; C23C 16/30; C23C 16/40

(52) U.S. Cl. CPC C23C 16/45525; C23C 16/402; C23C 16/405; C23C 16/407; C23C 16/345; C23C 16/303; C23C 16/40
USPC 428/212; 428/688; 428/421; 428/422; 428/480; 428/473.5; 428/523; 428/702; 428/698; 428/689; 428/446; 427/255.28

(57) ABSTRACT

A multi-layer structure including an interlayer to relieve stress in the structure, a device including the structure, and a method of forming the device and structure are disclosed. The structure includes a substrate having a first coefficient of thermal expansion, an interlayer, and a coating having a second coefficient of thermal expansion. The interlayer reduces stress in the structure that would otherwise exist in the structure as a result of the difference in coefficients of thermal expansion of the substrate and the coating.

### CROSS REFERENCE TO RELATED APPLICATIONS

This application claims the benefit of U.S. Provisional Patent Application Ser. No. 61/623,455, entitled MULTI-LAYER STRUCTURE INCLUDING AN INTERLAYER TO REDUCE STRESS IN THE STRUCTURE AND METHOD OF FORMING SAME, and filed Apr. 12, 2012, the disclosure of which is incorporated herein by reference to the extent such disclosure does not conflict with the present disclosure.

### GOVERNMENT LICENSE RIGHTS

This invention was made with government support under grant number FA9550-09-1-0053 awarded by the U.S. Air Force. The United States government has certain rights in the invention.

### THE NAMES OF PARTIES TO A JOINT RESEARCH AGREEMENT

The Regents of the University of Colorado, a body corporate, and E. I. du Pont de Nemours and Company of Wilmington, Del. are parties to a Joint Research Agreement.

### FIELD OF INVENTION

The present invention generally relates to structures including multiple layers, wherein the structures include an interlayer between two layers of differing coefficients of thermal expansion. The interlayer is used to reduce stress or strain that would otherwise result in the structure without the interlayer.

### BACKGROUND OF THE INVENTION

Structures including layers of different coefficients of thermal expansion may be used for a variety of purposes. For example, structures including a polymer substrate and an inorganic barrier layer may be used to form a gas diffusion barrier over the substrate suitable for various applications.

Fluorinated polymer substrates, such as ethylene tetrafluoroethylene (ETFE) or fluoroethylene propylene (FEP) are used to encapsulate solar devices, while polyester substrates, such as polyethylene naphthalate (PEN) are used for encapsulating organic light-emitting diode (OLED) structures, and similar devices. Use of polymers, such as FEP and ETFE, as encapsulants is desirable because they are relatively inert and can withstand outdoor conditions, including solar radiation, without degradation. However, polymers, such as FEP, ETFE and PEN, are relatively permeable to gases, such as oxygen and water vapor. Accordingly, an inorganic coating, such as aluminum oxide, may be applied to the polymer substrate to reduce the gas diffusion through the polymer.

To form the gas diffusion barrier, the inorganic material is often coated onto the substrate at an elevated temperature and then cooled to ambient temperature. Unfortunately, the polymer substrate and the coated inorganic material generally have very different coefficients of thermal expansion. Consequently, as the substrate and coating cool after the coating is deposited onto the substrate, or as the substrate and coating are otherwise exposed to changes in temperatures, stresses occur in the films, which can result in cracking of the films. If the inorganic film cracks, it may no longer function as a suitable diffusion barrier. Accordingly, improved structures including layers of differing coefficients of thermal expansion and methods of forming the structures are desired.

### SUMMARY OF THE INVENTION

The present invention generally relates to multi-layer structures that include an interlayer to reduce stress in layers adjacent the interlayer that would otherwise occur, because of a mismatch between the coefficients of thermal expansion of the layers that are adjacent the interlayer.

In accordance with exemplary embodiments of the invention, a structure includes a substrate having a first coefficient of thermal expansion, a coating having a second coefficient of thermal expansion, and an interlayer interposed between the substrate and the coating. In accordance with various aspects of these embodiments, the substrate includes a polymer, such as FEP, polyethylene naphthalate (PEN), polyethylene (PE), polypropylene (PP) or the like. In accordance with further aspects, the coating includes an inorganic material, such as a metal oxide (e.g., aluminum oxide). And, in accordance with yet additional exemplary aspects, the interlayer is a hybrid organic/inorganic material. In accordance with further aspects, the interlayer is formed using molecular layer deposition (MLD) techniques. And, in accordance with yet additional aspects, the coating is formed using atomic layer deposition (ALD) techniques. And, in accordance with further aspects, the coefficient of thermal expansion of the interlayer is graded along the thickness of the interlayer. In accordance with additional aspects, a desired thickness of the interlayer is dependent on one or more of: a thickness of the substrate, the substrate material, a thickness of the coating, the coating material, and the interlayer material.

In accordance with additional embodiments of the invention, a structure includes a substrate (e.g., a polymer), a hybrid organic/inorganic interlayer having a first surface and a second surface, the first surface of the interlayer adjacent the substrate, and an inorganic coating adjacent the second surface of the interlayer. In accordance with various aspects of these embodiments, the substrate includes, but is not restricted to, a polymer selected from one or more of FEP, PEN, ETFE, polyethylene (PE), polypropylene (PP) polytetrafluoroethylene (PTFE), polyvinyl fluoride (PVF), perfluoroalkoxy copolymer (PFA), polyethylene terephthalate (PET), polyimide (PI), polycarbonate (PC), polyarylate (PAR), polyethersulfone (PES), and polycylic olefin (PCO). In accordance with further aspects, the interlayer includes a material selected from one or more of various hybrid organic-inorganic polymers. One family of hybrid organic-inorganic polymers is the metal alkoxides known as metalcones such as alucone, zircone or titanicone. And, in accordance with yet additional aspects, the coating includes a metal oxide or nitride selected from one of more of aluminum oxide, SiO₂, TiO₂, ZrO₂, HfO₂, MoO₃, ZnO, SnO₂, In₂O₃, Ta₂O₅, Nb₂O₅, SiNₓ, and AlN. The interlayer may be deposited using plasma deposition techniques or MLD techniques. The coating may be formed by, for example, plasma deposition techniques or ALD techniques. In accordance with further aspects, the coefficient of thermal expansion of the interlayer is graded along the thickness of the interlayer. In accordance with additional embodiments, a desired thickness of the interlayer is dependent on one or more of: a thickness of the substrate, the substrate material, a thickness of the coating, the coating material, and the interlayer material.

In accordance with yet additional exemplary embodiments of the invention, a method of forming a structure includes providing a substrate having a first coefficient of thermal expansion, forming an interlayer overlying the substrate using MLD techniques, and forming a coating having a second coefficient of thermal expansion overlying the interlayer. In accordance with various aspects of these embodiments, the step of providing a substrate includes providing a polymer, such as FEP, PEN. PR. PP, or the like. In accordance with additional aspects, the step of forming an interlayer includes forming a hybrid organic/inorganic material. And, in accordance with yet additional aspects, the step of forming a coating includes using atomic layer deposition (ALD) techniques—e.g., to deposit inorganic material such as aluminum oxide.

In accordance with further embodiments of the invention, a method of forming a structure includes providing a substrate (e.g. a polymer), forming a hybrid interlayer overlying the substrate (e.g., using MLD techniques), and forming an inorganic coating overlying the interlayer (e.g., using ALD techniques). In accordance with various aspects of these embodiments, the step of providing a substrate includes providing a polymer, such as FEP or PEN.

In accordance with yet additional embodiments of the invention, a device (e.g., a solar cell or OLED) includes a multi-layered structure as described herein.

### BRIEF DESCRIPTION OF THE DRAWING FIGURES

The exemplary embodiments of the present invention will be described in connection with the appended drawing figures, in which:

FIG. 1 illustrates a multi-layer structure in accordance with exemplary embodiments of the invention;

FIG. 2 illustrates film cracking on structures without an interlayer;

FIGS. 3 and 4 illustrate FE-SEM images of cracks in a coating in structures without an interlayer;

FIG. 5 illustrates cracking density of films on structures without an interlayer;

FIG. 6 illustrates cracking density versus compressive stress for structures without an interlayer;

FIG. 7 illustrates FE-SEM images for interlayers formed on a substrate;

FIG. 8 illustrates cracking density of 48 nm coating overlying interlayers of various thicknesses in accordance with exemplary embodiments of the invention;

FIG. 9 illustrates cracking density of 21 nm coatings overlying interlayers of various thicknesses in accordance with exemplary embodiments of the invention;

FIG. 10 illustrates compressive stress of coatings as a function of interlayer thickness in accordance with exemplary embodiments of the invention;

FIG. 11 illustrates properties of interlayers in accordance with exemplary embodiments of the invention; and

FIG. 12 illustrates crack density versus tensile strain of exemplary structures in accordance with exemplary embodiments of the invention.

It will be appreciated that the figures are not necessarily drawn to scale. For example, the dimensions of some of the elements in the figures may be exaggerated relative to other elements to help to improve understanding of illustrated embodiments of the present invention.

### DETAILED DESCRIPTION OF PREFERRED EMBODIMENTS OF THE INVENTION

The description of exemplary embodiments of the present invention provided below is merely exemplary and is intended for purposes of illustration only; the following description is not intended to limit the scope of the invention disclosed herein. Moreover, recitation of multiple embodiments having stated features is not intended to exclude other embodiments having additional features or other embodiments incorporating different combinations of the stated features.

The present disclosure provides improved multi-layer structures, having reduced stress in layers having different coefficients of thermal expansion, devices including the structures, methods of forming the structures and devices. As set forth in more detail below, multi-layer structures, in accordance with various exemplary embodiments of the invention, include an interlayer, which serves to reduce stress, strain, and/or cracking of layers within the structure.

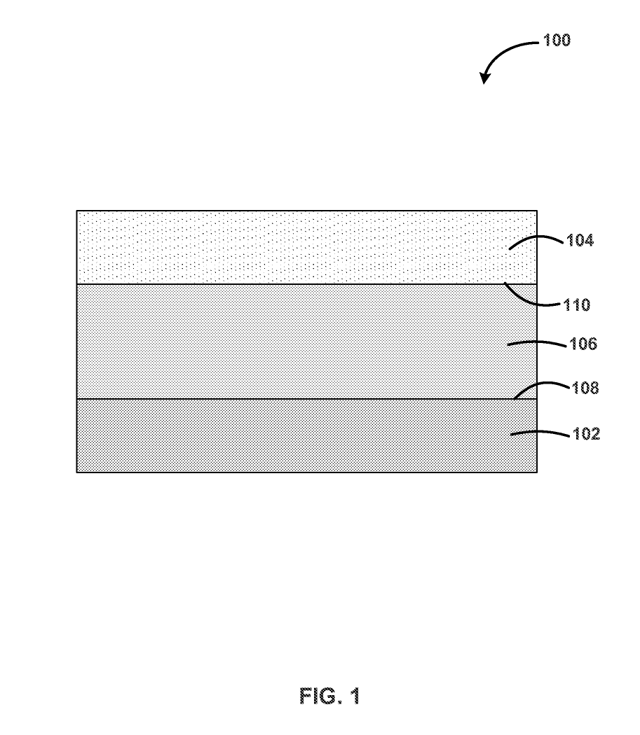

FIG. 1 illustrates a structure 100 in accordance with exemplary embodiments of the invention. Structure 100 includes a substrate 102, a coating or layer 104, and an interlayer 106 interposed between substrate 102 and layer 104.

Substrate 102 may be formed of a variety of materials. For example, substrate 102 may be a polymeric material such as a fluoropolymer (e.g., fluorinated ethylene propylene (FEP), heat-stabilized polyethylene naphthalate (HSPEN), PEN, polyethylene (PE), polypropylene (PP) ETFE, polytetrafluoroethylene (PTFE), polyvinyl fluoride (PVA), perfluoroalkoxy copolymer (PFA), polyethylene terephthalate (PET), polyimide (PI), polycarbonate (PC), polyarylate (PAR), polyethersulfone (PES), polycylic olefin (PCO), or the like). Such materials may be suitable for encapsulating devices, such as thin-film photovoltaic devices, organic light-emitting diode devices, and the like. Alternatively, substrate 102 may include rigid material, such as semiconductor material, which may form part of, for example, an electronic device or circuit. By way of examples, substrate 102 includes a polymer, such as FEP or HSPEN. As used herein, “substrate” refers to a layer within a structure that may be a support or another layer deposited onto the support.

Layer 104 may include any material that has a different coefficient of thermal expansion than substrate 102. The difference in coefficient of thermal expansion may be at least about 2:1, or at least about 3:1, or at least about 10:1, or at least about 20:1, or at least about 30:1, or at least about 40:1 ratio. The percent strain in the coating and the substrate that would result in the absence of interlayer 106 may be at least about 0.5% or at least about 1%, or enough strain or stress to cause damage to one or more of the layers of the structure. By way of examples, layer 104 includes one or more inorganic materials, such as metal oxides or metal nitrides (e.g., aluminum oxide, SiO₂, TiO₂, ZrO₂, HfO₂, MoO₃, ZnO, SnO₂, In₂O₃, Ta₂O₅, Nb₂O₅, SiNₓ, or MN). The coating may be amorphous and may be used as a diffusion barrier on various devices. As set forth in more detail below, layer 104 may be deposited using atomic layer deposition (ALD) techniques.

Interlayer 106 serves to relieve stress and/or strain that would otherwise occur in structures including layer 104 deposited on or formed adjacent to substrate 102. Interlayer 106 may have a coefficient of thermal expansion between the respective coefficients of thermal expansion of substrate 102 and layer 104. In accordance with various examples, interlayer 106 may be functionally graded, such that the coefficient of thermal expansion of interlayer 106 varies in accordance with the thickness of interlayer 106, indicated by “d” in FIG. 1 (i.e., layer 106 may be a functionally graded hybrid organic/inorganic interlayer). For example, interlayer 106 may have a high coefficient of thermal expansion at or near an interface 108 of substrate 102 and interlayer 106 and have a relatively low coefficient of thermal expansion at or near an interface 110 of layer 104 and interlayer 106, with a graded transition of coefficients of thermal expansion between the interfaces. Alternatively, the interlayer may be homogeneous (e.g., a homogeneous hybrid organic-inorganic interlayer).

In accordance with exemplary embodiments, interlayer 106 includes a hybrid organic-inorganic material. The metal alkoxides are one possible class of hybrid organic-inorganic polymers. One exemplary metal alkoxide suitable for use with embodiments of the disclosure is poly(aluminum ethylene glycol) known as alucone. Other possible metal alkoxides are zircone and titanicone. These hybrid organic/inorganic polymers can be formed or grown using, for example, molecular layer deposition (MLD) techniques. Alternatively, the interlayer could be another class of polymer(s), such as polymers derived from metal esters—e.g., derived from organic acids, metal alkyl amines—e.g., derived from organic amines, or the like.

The amount of stress relieved in structure 100 may be a function of substrate 102 thickness, substrate 102 material, layer 104 thickness, layer 104 material, interlayer 106 thickness, and/or interlayer material.

### SPECIFIC EXAMPLES

The following non-limiting examples illustrate exemplary multi-layer structures in accordance with various embodiments of the disclosure. These examples are merely illustrative, and it is not intended that the invention be limited to the examples. Compositions of various layers in accordance with the present invention may include the compounds and materials listed below as well as additional and/or alternative materials, and various layers and materials described below may be interchanged with similar materials and layers described in connection with other structures.

In the examples described below, alucone was deposited onto substrates using MLD, and aluminum oxide (Al₂O₃) was deposited onto the alucone layer using ALD. As illustrated in the examples provided below, the alucone layer reduced or eliminated cracking in the ALD films that would otherwise occur without the inclusion of interlayer.

The Al₂O₃ ALD and alucone MLD films were grown in a hot-wall, viscous flow reactor. The films were deposited at a growth temperature of about 135° C. on FEP (Teflon, DuPont) with substrate thicknesses of about 50 μm and about 125 μm or HSPEN (DuPont, Teijin, Inc.) with a substrate thickness of about 25 μm. The reactants were alternately injected into an ultrahigh purity N₂ viscous flow carrier gas continuously traveling through the reactor. The baseline reactor pressure was 600 mTorr with N₂ flowing through the reactor.

The alucone MLD films were grown using an ABC reactant sequence with TMA, HOCH₂CH₂OH (ethylene glycol (EG)) and H₂O as the reactants. These alucone MLD films have some remaining AlCH₃ species that can react with H₂O and lead to some film instability. The H₂O in the ABC reactant sequence helps to remove the AlCH₃ species. For this ABC alucone MLD process, the three sequential, self-limiting reactions are:

AlOH*+Al(CH₃)₃→AlOAl(CH₃)₂*+CH₄ (A)

AICH₃*+HOCH₂CH₂OH→AIOCH₂CH₂OH*+CH₄ (B)

AlCH₃*+H₂O→AlOH*+CH₄ (C)

where the asterisks indicate the surface species.

For alucone MLD film growth, the timing for the ABC alucone MLD reactant sequence was (t₁, t₂, t₃, t₄, t₅, t₆), where t₁ and t₂ are the TMA dosing time and the N₂ purge time following the TMA exposure, t₃ and t₄ are the EG dosing time and the N₂ purge time following the EG exposure, and t₅ and t₆ are the water dosing time and the N₂ purge time following the H₂O exposure. The timing sequence was (0.6, 75, 0.9, 120, 0.2, 120) where the times are in seconds. The repetition of the ABC cycles results in an alucone MLD film growth of ˜2 Å per AB cycle at 135° C.

Al₂O₃ ALD was performed using Al(CH₃)₃ (trimethylaluminum (TMA)) and H₂O (water) as the reactants. The two sequential, self-limiting reactions for Al₂O₃ ALD are:

AlOH*+AI(CH₃)₃→AlOAl(CH₃)₂*+CH₄ (A)

ALCH₃*+H₂O→AlOH*+CH₄ (B)

For Al₂O₃ ALD film growth, the substrate is first exposed to TMA, and then after N₂ purging to remove residual reactants and reaction products, the substrate is exposed to water and a second N₂ purging process. This sequence defines one AB cycle for Al₂O₃ ALD. The timing for this sequence was (t₁, t₂, t₃, t₄) where t₁ is the TMA exposure time, t₂ is the N₂ purging time, t₃ is the water exposure time and t₄ is the second N₂ purging time. The timing sequence was (0.8, 75, 0.2, 75) where the times are again in seconds. The reactant pressures were both 250 mTorr. The repetition of the AB cycles results in an Al₂O₃ ALD film growth of ˜1.2 Å per AB cycle at 135° C.

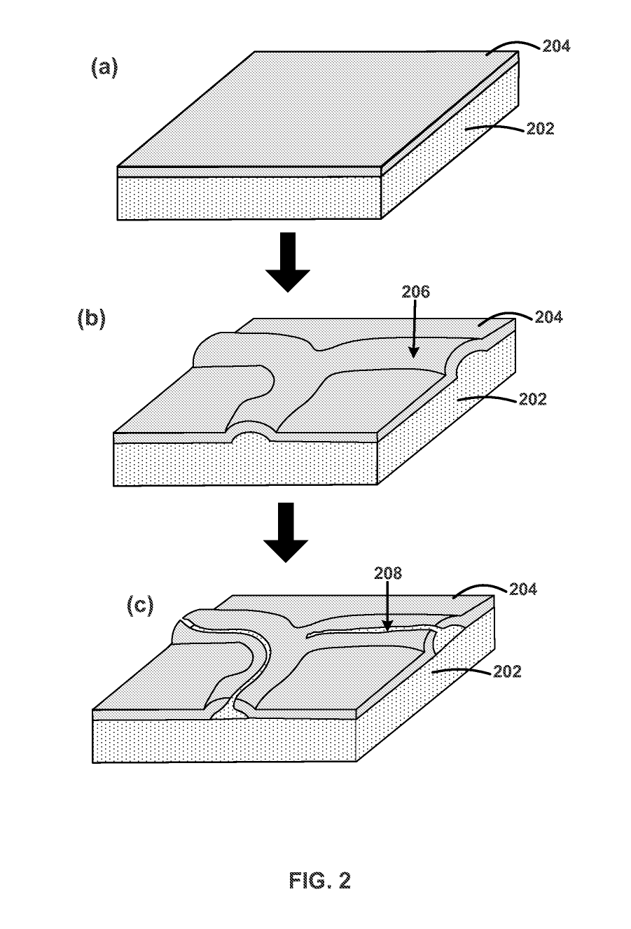

FIG. 2 illustrates compressive strain that forms in an Al₂O₃ layer 204 overlying a substrate 202 when no interlayer is included in a structure. The Al₂O₃ films are deposited at the temperature noted above (FIG. 2(a)), and as the structure cools to room temperature, the Al₂O₃ film is placed under compressive stress, because the FEP substrate contracts more than the Al₂O₃ layer. As the structure cools, the compressive stress initially causes buckles 206 to form in the Al₂O₃ film (FIG. 2(b)). As the cooling continues, the compressive stress increases, and the Al₂O₃ film begins to form cracks 208—e.g., along the ridges of the buckles 206 (FIG. 2(c)).

The residual thermal stress of a film overlying a substrate can be modeled using the Ravichandran model, below.

$$\begin{matrix}{σ}_{res} ( y ) = E ( y ) Δ T [ α ( y ) - \frac{{A}_{1}}{{E}_{1}} - \frac{( {A}_{2} - \frac{{A}_{1}}{{E}_{1}} {E}_{2} ) ( {yE}_{1} - {E}_{2} )}{( {E}_{1} {E}_{3} - {E}_{2}^{2} )} ] & ( 1 ) \\ {A}_{1} = {\int }_{- c}^{c} α ( y ) E ( y ) d y & ( 2 ) \\ {A}_{2} = {\int }_{- c}^{c} α ( y ) E ( y ) y d y & ( 3 ) \\ {E}_{1} = {\int }_{- c}^{c} E ( y ) d y & ( 4 ) \\ {E}_{2} = {\int }_{- c}^{c} E ( y ) y d y & ( 5 ) \\ {E}_{3} = {\int }_{- c}^{c} E ( y ) {y}^{2} d y & ( 6 )\end{matrix}$$

In these equations, the variable y is normal to the surface of the polymer substrate and parallel to the growth direction of the film coatings. y varies from −c to +c. −c starts at the bottom of the substrate. +c ends at the top of the coating. Given the much larger thickness of the polymer substrate compared with the film coatings, in these examples, the y=0 point is inside the polymer substrate. The thermal expansion coefficient and elastic modulus for each component in the system are given by α(y) and E(y), respectively. The thermal expansion coefficients for the FEP substrate, alucone interlayer and Al₂O₃ ALD film were 120-170 ppm/K in the temperature range from room temperature to 160° C., 12 ppm/K and 4.2 ppm/K, respectively. The elastic moduli for the FEP substrate, alucone interlayer and Al₂O₃ ALD film were 0.48 GPa, 36.8 GPa and 180 GPa, respectively.

The A1 and A2 terms in Equations 2 and 3 yield the symmetric and asymmetric stress of the whole system. E1 in Equation 4 is the symmetrical term of the elastic modulus. E2 and E3 in Equations 5 and 6 are the asymmetric terms of the elastic modulus. A positive residual thermal stress is a tensile stress. A negative thermal stress is a compressive stress.

Critical Tensile Strain of Alucone MLD Films on FEP and HSPEN Substrates

The critical tensile strains of alucone MLD films were measured on FEP and HSPEN substrates. For these measurements, sheets of FEP and HSPEN were cut into strips with dimensions of 100 mm×10 mm (gauge section) using a paper cutter. The FEP and HSPEN strips then were loaded into the reactor for alucone MLD coating. After alucone MLD coating, the FEP and HSPEN sample strips were cooled to room temperature.

A mechanical tester (Insight 2, MYS Systems Corp.) was used to stress the samples. The tensile strain was applied at the displacement controlled strain rate of 0.015 s⁻¹. The strain was measured with the laser extensometer (LE-05, Electronic Instrument Research Corp.). The cracks from strain on the alucone MLD thin film were examined with a confocal microscope (LSM 510, Carl Zeiss, Inc.) with optical visualization using light scattering. To detect cracks easily with the confocal microscope, the samples were soaked in 0.01N HCl solution for 90 min to etch away ˜50 nm of alucone MLD film after stressing to a particular tensile strain. The samples were washed with distilled and deionized water to remove the residue HCl solution and then dried using ultra-high purity N₂ gas. An argon ion laser with the wavelength of 458 nm was then used to examine the cracking of the alucone MLD film. The cracking density was determined from the number of cracks along the direction of the tensile strain over a length 90 μm. The crack density and uncertainty were averaged for 5 different images.

Al₂O₃ ALD Film Cracking on FEP Substrates

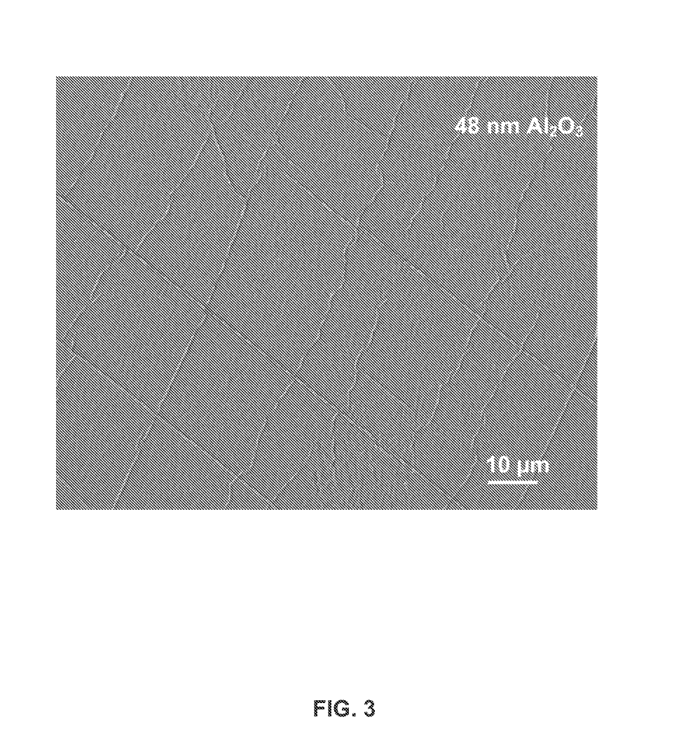

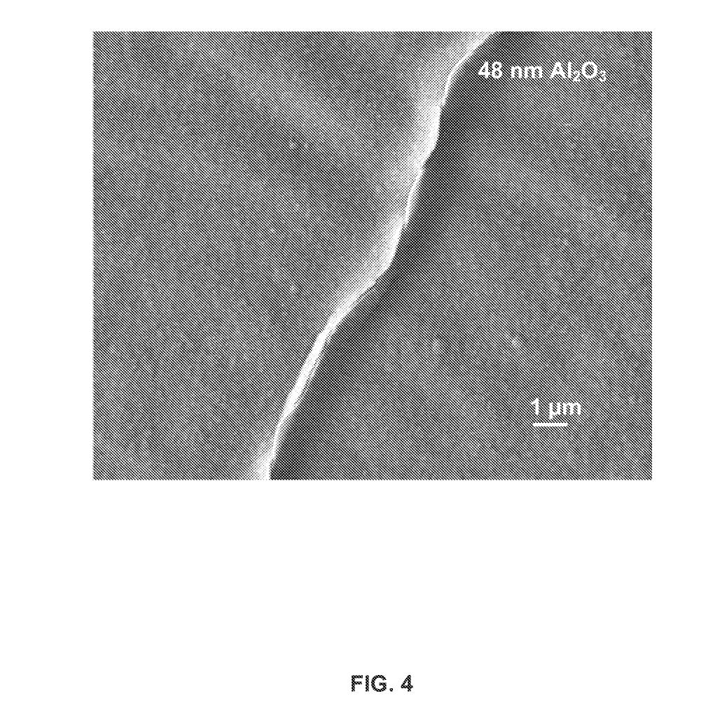

A FE-SEM image of Al₂O₃ ALD films that have buckled and cracked on FEP is shown at low magnification in FIG. 3. This image is for an Al₂O₃ ALD film with a thickness of 48 nm. The Al₂O₃ ALD film was deposited at 135° C. on a FEP substrate with a thickness of 125 μm. The compressive stress on this Al₂O₃ ALD film was 1.58 GPa. This compressive stress was calculated using the Ravichandran model given by Equation 1, above. The FE-SEM image of one of the buckles that has cracked is displayed at high magnification in FIG. 4.

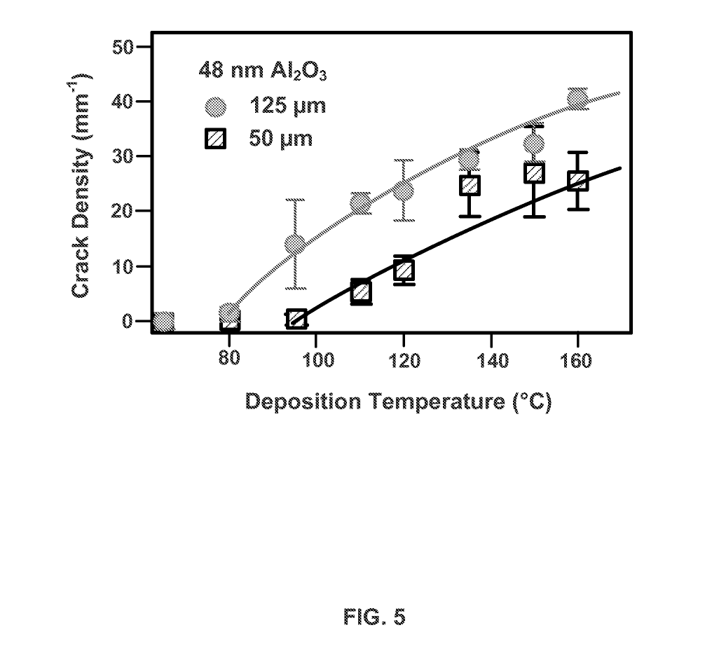

The crack density in Al₂O₃ ALD films was measured after deposition at different temperatures on FEP substrates with thicknesses of 50 μm and 125 μm. The thickness of the Al₂O₃ ALD film was 48 nm. FIG. 5 shows the cracking density in the Al₂O₃ ALD film on the FEP substrates versus deposition temperature. The solid lines show a fit to the using an exponential expression with the form y=y₀(1−exp[−b(T−T₀)]). The threshold deposition temperatures, T₀, for cracking are ˜78° C. and ˜95° C. for the FEP substrates with thicknesses of 125 μm and 50 μm, respectively.

The Ravichandran model for the thermal stress was used to calculate stress because the deposition temperatures apply different compressive stresses to the Al₂O₃ ALD film depending on the thickness of the FEP substrate. The thicker FEP substrate is constrained less by the Al₂O₃ ALD film than the thinner FEP substrate. Conversely, the thicker FEP substrate applies larger compressive stress to the Al₂O₃ ALD films. This larger compressive stress leads to a cracking threshold at a lower deposition temperature of ˜78° C. for the FEP substrate with a thickness of 150 μm. Higher deposition temperatures produce higher compressive strains and larger crack densities.

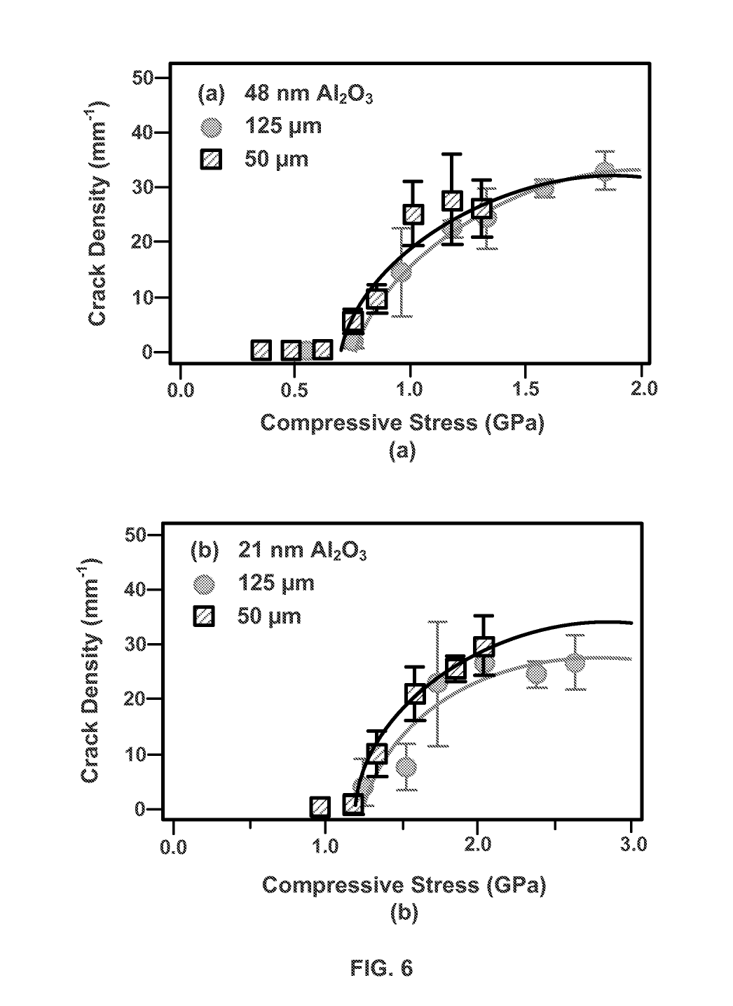

The cracking density versus deposition temperature in FIG. 5 can be replotted as cracking density versus compressive stress in FIG. 6(a). When the Ravichandran model is employed, the Al₂O₃ ALD film with a thickness of 48 nm is observed to crack at the same critical compressive stress for both FEP substrate thicknesses of 50 μm and 125 μm. The identical critical compressive stress for the two FEP substrate thicknesses supports the validity of the Ravichandran model.

The solid lines in FIG. 6(a) are based on the exponential fitting form: y=y₀(1−exp[−b(σ−σ₀)]). In this expression, y is the crack density, y₀ is the saturation crack density, σ is the compressive stress, σ₀ is the critical compressive stress and b is an adjustable parameter. The fitting closely approximates the measured crack density versus compressive stress and determines the critical compressive stress, σ₀, when σ−σ₀=0. The critical compressive stress for the Al₂O₃ ALD film with a thickness of 48 nm on FEP substrates with thicknesses of 50 μm and 125 μm were 0.74±0.04 GPa and 0.73±0.29 GPa, respectively.

FIG. 6(b) illustrates the cracking density for Al₂O₃ ALD films with a thickness of 21 nm on FEP substrates with thicknesses of 50 and 125 μm. The Ravichandran model again predicts the same critical compressive stress for both FEP substrate thicknesses. The identical critical compressive stress for the two FEP substrate thicknesses further indicates that the Ravichandran model is correctly accounting for the compressive stress on the Al₂O₃ ALD films. The solid lines based on the exponential forms reveal that the critical compressive stresses for the Al₂O₃ ALD film with a thickness of 21 nm on FEP substrates with thicknesses of 50 μm and 125 μm, were 1.18±0.09 GPa and 1.16±0.02 GPa, respectively.

No Cracking for Alucone MLD Films on FEP Substrates

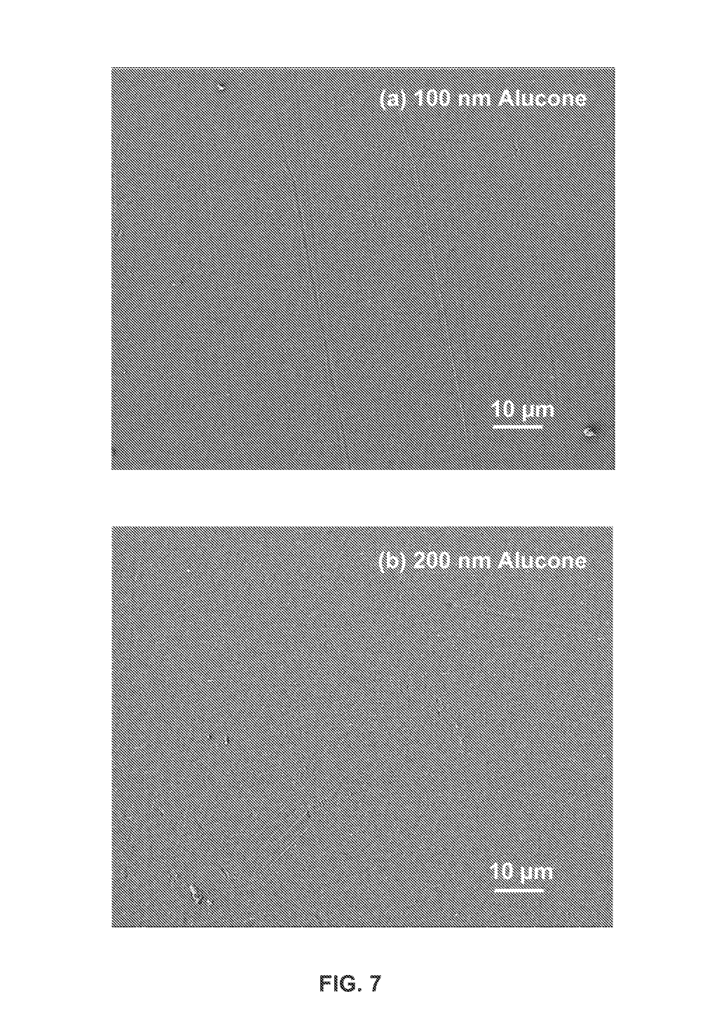

Experiments were first conducted to determine if there was any cracking in the alucone MLD films by themselves on the FEP substrates. There was no evidence of any cracking or buckling in the alucone MLD films on the FEP substrates over the entire range of deposition temperatures and compressive stresses. FIG. 7 illustrates FE-SEM images for alucone MLD films deposited at 135° C. and then cooled down to room temperature on FEP substrates with a thickness of 125 μm. The alucone MLD films with thicknesses of 100 nm and 200 nm are shown in FIGS. 7(a) and 7(b), respectively.

The thermal compressive stress applied to the alucone MLD films with a thickness of 100 nm in FIG. 7(a) is calculated to be σ=0.39 GPa using the Ravichandran model. This calculation used an elastic modulus of E_{f}=36.8 GPa and a constant thermal expansion coefficient of α_{f}=12 ppm/K for the alucone MLD film. Using the relationship E=σ/ε, the compressive stress of σ=0.39 GPa is equivalent to a compressive strain of ε=−1.06%. For comparison, the thermal compressive stress applied to the alucone MLD film with a thickness of 200 nm in FIG. 7(b) is calculated to be σ=0.32 GPa using the Ravichandran model.

Alucone MLD films with thicknesses of 20 nm, 40 nm and 60 nm were also deposited at 135° C. and then cooled to room temperature and examined by FE-SEM. None of the FE-SEM images showed any buckling or cracking. The alucone MLD films with thicknesses of 100 nm and 200 nm were also deposited at 135° C. and then cooled down to 78° C. using a mixed dry ice and methanol solution. The FE-SEM images of these films also displayed no evidence of any buckling or cracking. The alucone MLD films are able to withstand high compressive strains without cracking.

In contrast to the absence of cracking at high compressive strains, earlier studies revealed that the critical tensile strain of alucone MLD films with a thickness of 100 nm was only ε=0.69%. This low critical tensile strain was attributed to the lack of cross-linking in the alucone MLD films which enables the films to be easily pulled apart. For compressive strains, this lack of cross-linking may be a benefit because the polymer chains in the alucone MLD layer can easily move with respect to each other under compression without cracking.

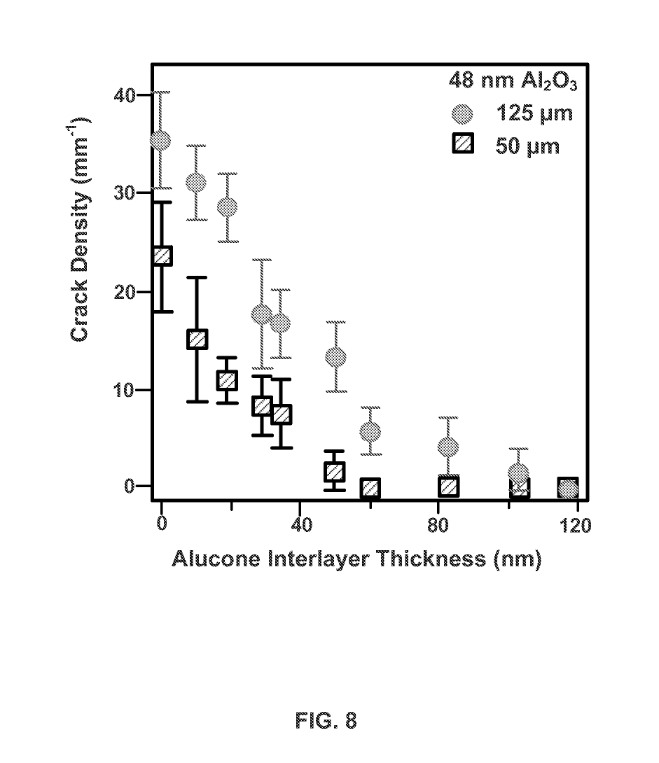

Alucone MLD films were able to reduce dramatically the cracking density in the Al₂O₃ ALD films. The reduction of the cracking density was larger for thicker alucone MLD interlayers. FIG. 8 shows the cracking density in the Al₂O₃ ALD film with a thickness of 48 nm versus the thickness of the alucone MLD interlayer. The Al₂O₃ ALD films and alucone MLD interlayers were both deposited at 135° C. on the FEP substrates with thicknesses of 50 μm and 125 μm. The cracking density is reduced with the increasing thickness of the alucone MLD interlayer. No cracks are measured for alucone MLD interlayer thicknesses of >50 nm on the 50 μm FEP substrates and >110 nm on the 125 μm FEP substrates.

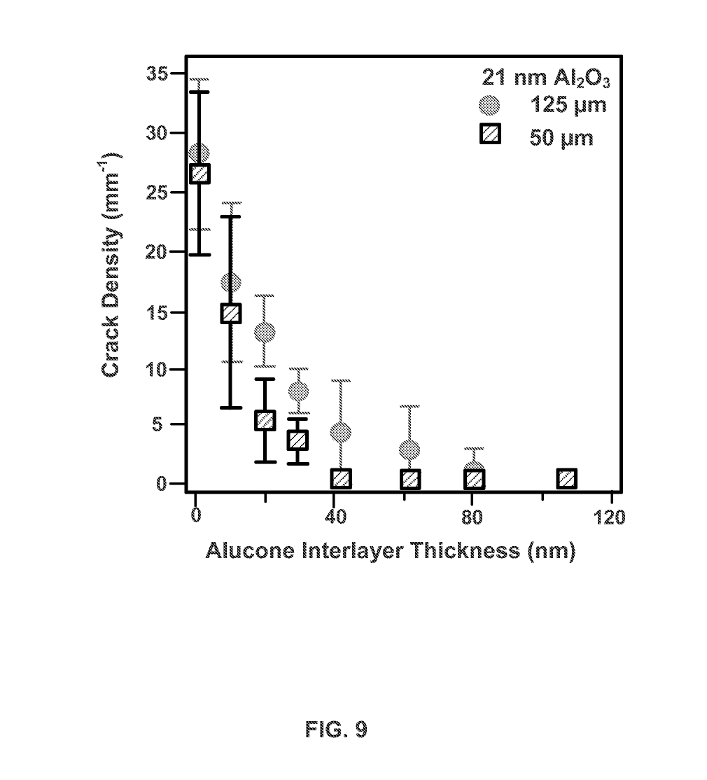

The reduction of the cracking density was more dramatic for thinner Al₂O₃ ALD films. FIG. 9 illustrates the cracking density in the Al₂O₃ ALD film with a thickness of 21 nm versus the thickness of the alucone MLD interlayer. The Al₂O₃ ALD films and alucone MLD interlayers were again both deposited at 135° C. on the FEP substrates with thicknesses of 50 μm and 125 μm. The cracking density is more rapidly reduced with the thickness of the alucone MLD interlayer. No cracks are measured for alucone MLD interlayer thicknesses of >40 nm on the 50 μm FEP substrates and >100 nm on the 125 μm FEP substrates.

The alucone MLD interlayer is able to reduce the stress on the Al₂O₃ ALD film resulting from thermal expansion mismatch with the underlying FEP substrates. The elimination of cracking in the Al₂O₃ ALD film indicates that the alucone MLD interlayer is able to reduce the compressive stress to below the critical compressive stress of the Al₂O₃ ALD film. Thinner Al₂O₃ ALD films have higher critical compressive stresses. The results in FIGS. 8 and 9 are consistent with higher critical compressive stresses for the thinner Al₂O₃ ALD films.

The crack densities versus alucone interlayer thickness in FIGS. 8 and 9 can be compared with the crack densities versus compressive stress in FIG. 6 for the same Al₂O₃ ALD film thicknesses without the alucone interlayer. Assuming that the measured crack density correlates with a particular compressive stress, compressive stresses can be assigned to the crack densities in FIGS. 8 and 9 using the measured crack densities versus compressive stress in FIG. 6.

For example, FIG. 8 indicates that the cracking density is 17.6 mm⁻¹ for the Al₂O₃ ALD film with the thickness of 48 nm on an alucone interlayer with the thickness of 29.2 nm on a FEP substrate with a thickness of 125 μm. FIG. 6(a) indicates that a crack density of 17.6 mm⁻¹ occurs at a compressive stress of ˜1.06 GPa. This correlation indicates that a compressive stress of ˜1.06 GPa must have been present on the Al₂O₃ ALD film with a thickness of 48 nm on the alucone interlayer with a thickness of 29.2 nm on the FEP substrate with a thickness of 125 μm.

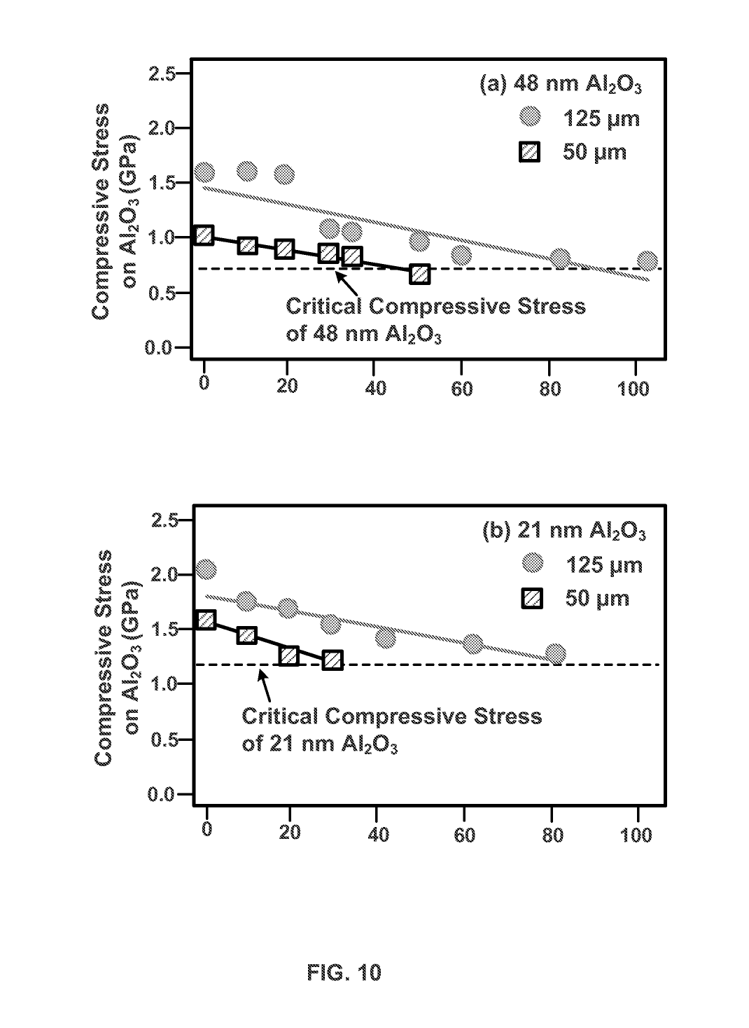

The cracking densities in FIGS. 8 and 9 can be redefined as corresponding compressive stresses using the crack density versus compressive stress information in FIG. 6. Using this correspondence, FIG. 10 illustrates the compressive stress on the Al₂O₃ ALD film versus alucone interlayer thickness. The alucone interlayer progressively reduces the compressive stress on the Al₂O₃ ALD film as a function of alucone interlayer thickness. The dashed lines in FIGS. 10(a) and 10(b) show the critical compressive stresses for the Al₂O₃ ALD films with thicknesses of 21 nm and 48 nm, respectively. The solid lines in FIG. 10 illustrate the linear fitting of the compressive stress versus the alucone interlayer thickness.

The compressive stress reduction versus alucone interlayer thickness can be derived from the linear fits to the data in FIGS. 10(a) and 10(b). For the Al₂O₃ ALD film with a thickness of 48 nm on FEP substrates with thicknesses of 50 μm and 125 μm, the compressive stress reductions were 6.3 MPa/nm and 8.0 MPa/nm, respectively. For the Al₂O₃ ALD film with a thickness of 21 nm on FEP substrates with thicknesses of 50 μm and 125 μm, the compressive stress reductions were 12.7 MPa/nm and 7.3 MPa/nm, respectively. The compressive stress reductions are fairly similar for the various Al₂O₃ ALD film thicknesses and FEP substrate thicknesses. The average compressive stress reduction per thickness of the alucone interlayer is 8.5±2.3 MPa/nm.

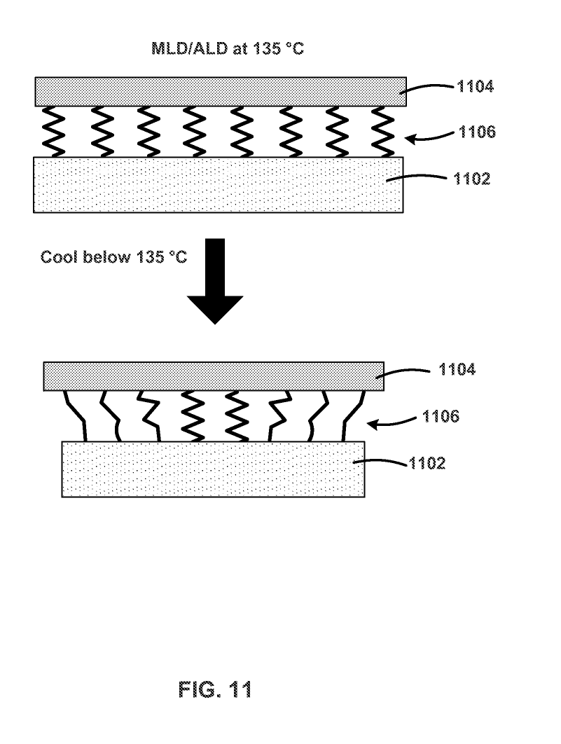

FIG. 11 illustrates a pictorial illustration of the reduction of compressive stress on an Al₂O₃ ALD film 1104 by an alucone interlayer 1106 overlying a substrate 1102. With cooling from deposition temperature (e.g., 135° C.) to room temperature, the FEP substrate will contract more than the Al₂O₃ ALD film. This mismatch of thermal expansion coefficients leads to compressive stress on the Al₂O₃ ALD film. However, the “spring-like” alucone interlayer with minimal cross-linking between the polymer chains absorbs some of the compressive stress and lowers the compressive stress applied to the Al₂O₃ ALD film. Consequently, the alucone interlayer is able to protect the Al₂O₃ ALD film from buckling and cracking.

Critical Tensile Strain of Alucone MLD Films on FEP and HSPEN Substrates

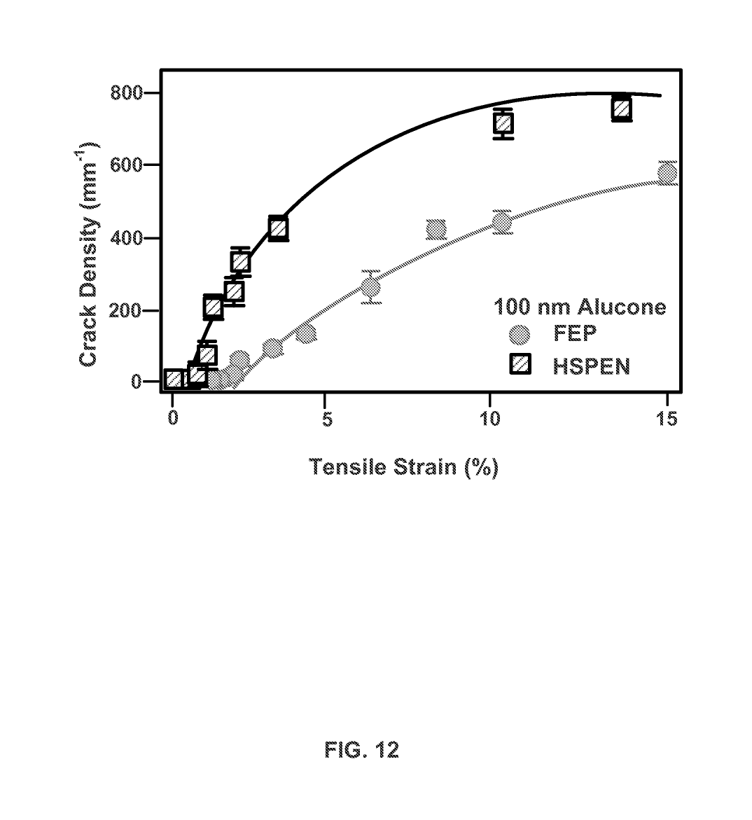

The results for the crack density versus tensile strain for alucone MLD films with a thickness of 100 nm deposited on FEP and HSPEN substrates at 135° C. are shown in FIG. 12. The critical tensile strain of the alucone MLD film on the FEP substrate was much higher than the critical tensile strain for the alucone MLD film with the same thickness on the HSPEN substrate. The critical tensile strains were obtained by fitting the results using an exponential fitting form similar to the technique described above. Critical tensile strains for the alucone MLD film with a thickness of 100 nm were 1.96±0.00% on FEP and 0.61±0.12% on HSPEN.

The higher critical tensile strain on the FEP substrate can be explained by the higher residual compressive stress in the alucone MLD films grown on the FEP substrates. The compressive stress in the alucone MLD film deposited at 135° C. on the FEP substrate and then cooled to room temperature is calculated to be σ=0.39 GPa using the Ravichandran model. This compressive stress equates to a compressive strain of ε=1.06% based on an elastic modulus of E=36.8 GPa. This large residue compressive strain can then help offset the applied tensile strain.

It is thought that the tensile strain applied to the alucone MLD film on FEP first reduces the residual compressive strain in the alucone MLD film. After removal of the compressive strain, the applied tensile strain then leads to a net tensile strain in the alucone MLD film. A critical tensile strain of E=1.96% is observed for the alucone MLD film on FEP. This critical tensile strain is close to the residual compressive strain of 1.06% added to the critical tensile strain of 0.61% for cracking of the alucone MLD film on HSPEN. Adding the two strains assumes that the critical tensile strains for alucone MLD films on HSPEN are not affected by residual compressive strains.

The alucone MLD films deposited on HSPEN will have a much smaller residual thermal stress resulting from the thermal expansion coefficient mismatch between the Al₂O₃ ALD film and the HSPEN substrate. Compared with the thermal expansion coefficient of 120-160 ppm/K for FEP, the HSPEN has a much smaller linear thermal expansion coefficient of 13 ppm/K. Consequently, the mismatch between the thermal expansion coefficients of the Al₂O₃ ALD film and the HSPEN substrate yields a small residue compressive stress of 5.33 MPa or a compressive strain of only ε=0.014%. The compressive stress was calculated using the Ravichandran model after deposition at 135° C. and cooling to 25° C.

The present invention has been described above with reference to a number of exemplary embodiments and examples. It should be appreciated that the particular embodiments shown and described herein are illustrative of the preferred embodiments of the invention and its best mode, and are not intended to limit the scope of the invention as set forth in the claims. It will be recognized that changes and modifications may be made to the embodiments described herein without departing from the scope of the present invention. These and other changes or modifications are intended to be included within the scope of the present invention, as expressed in the following claims and the legal equivalents thereof.

1. A multi-layer structure comprising:
a substrate having a first coefficient of thermal expansion;
a coating having a second coefficient of thermal expansion; and
a hybrid organic/inorganic interlayer interposed between the substrate and the coating,
wherein the hybrid organic/inorganic interlayer has a first surface and a second surface, the first surface adjacent the substrate and the second surface adjacent the coating.

2. The multi-layer structure of claim 1, wherein the hybrid organic/inorganic interlayer is deposited using molecular layer deposition techniques.

3. The multi-layer structure of claim 1, wherein the hybrid organic/inorganic interlayer comprises one or more metal alkoxides.

4. The multi-layer structure of claim 1, wherein the hybrid organic/inorganic interlayer comprises alucone, zircone, or titanicone.

5. The multi-layer structure of claim 1, wherein a coefficient of thermal expansion of the hybrid organic/inorganic interlayer is graded along a thickness of the hybrid organic/inorganic interlayer.

6. The multi-layer structure of claim 1, wherein a coefficient of thermal expansion of the hybrid organic/inorganic interlayer is homogeneous along a thickness of the hybrid organic/inorganic interlayer.

7. The multi-layer structure of claim 1, wherein the coating is formed using atomic layer deposition techniques.

8. The multi-layer structure of claim 1, wherein the substrate is a polymer.

9. The multi-layer structure of claim 8, wherein the polymer is selected from the group consisting of fluoroethylene propylene (FEP), heat-stabilized polyethylene naphthalate (HSPEN), ethylene tetrafluoroethylene (ETFE), polytetrafluoroethylene (PTFE), polyvinyl fluoride (PVF), perfluoroalkoxy copolymer (PFA), polyethylene terephthalate (PET), polyimide (PI), polycarbonate (PC), polyarylate (PAR), polyethersulfone (PES), and polycylic olefin (PCO).

10. The multi-layer structure of claim 1, wherein the coating comprises a materials selected from the group consisting of metal oxide and metal nitride.

11. The multi-layer structure of claim 10, wherein the metal oxide is aluminum oxide.

12. The multi-layer structure of claim 10, wherein the coating comprises an amorphous material.

13. The multi-layer structure of claim 1, wherein a thickness of the hybrid organic/inorganic interlayer is based on one or more of: substrate material, substrate thickness, coating material, coating thickness, and the hybrid organic/inorganic interlayer material.

14. The multi-layer structure of claim 1, wherein a difference between the first coefficient of thermal expansion and the second coefficient of thermal expansion is at least about 2:1.

15. The multilayer structure of claim 1, wherein the coating comprises one or SiO₂, TiO₂, ZrO₂, HfO₂, MoO₃, ZnO, SnO₂, In₂O₃, Ta₂O₅, Nb₂O₅, SiNₓ, and AlN.

16. A method of forming a structure, the method comprising the steps of:
providing a substrate having a first coefficient of thermal expansion;
forming a hybrid organic/inorganic interlayer overlying the substrate; and
forming a coating having a second coefficient of thermal expansion overlying the hybrid organic/inorganic interlayer.

17. The method of forming a structure of claim 16, wherein the step of forming a coating comprises atomic layer deposition.

18. The method of forming a structure of claim 16, wherein the step of forming the hybrid organic/inorganic interlayer comprises molecular layer deposition.

19. A device comprising the multi-layer structure of claim 1.

20. The device of claim 19, wherein the hybrid organic/inorganic interlayer is deposited using molecular layer deposition techniques.
